(19) United States
(12) Patent Application Publication
(10) Pub. No.: US 2006/0290377 A1
(43) Pub. Date: Dec. 28, 2006

(54) Capacitively coupled pulsed signaling bus interface

(76) Inventors: Jongsun Kim, Los Angeles, CA (US); Ingrid Verbauwhede, Santa Monica, CA (US); Mau-Chung F. Chang, Los Angeles, CA (US)

Correspondence Address: GATES & COOPER LLP;HOWARD HUGHES CENTER, 6701 CENTER DRIVE WEST, SUITE 1050, LOS ANGELES, CA, 90045, US

(21) Appl. No.: 11/444,009

(22) Filed: May 31, 2006

Related U.S. Application Data
(60) Provisional application No. 60/685,859, filed on May 31, 2005.

(51) Int. Cl. H03K 17/16

(52) U.S. Cl. 326/30

(57) ABSTRACT

A fully alternating current (AC) coupled multi-point, multi-drop or point-to-point bus interconnect uses a low power synchronous pulsed signaling scheme for board-level chip-to-chip communication. A single-ended or differential pulsed signaling transceiver generates a diamond data eye with a small time constant in the pulsed signal. The transceiver includes a high-pass filter or a differentiator circuit network that generates triangle pulses that make the diamond data eye.

### CROSS-REFERENCE TO RELATED APPLICATIONS

This application is related to the following co-pending and commonly-assigned application:

U.S. Provisional Patent Application Ser. No. 60/685,859, filed on May 31, 2005, by Jongsun Kim, Ingrid Verbauwhede, and Mau-Chung F. Chang, entitled “CAPACITIVELY COUPLED PULSED SIGNALING BUS INTERFACE,” attorneys docket number 30435.171-US-P1 (2005-352-1);

which application is incorporated by reference herein.

### STATEMENT REGARDING FEDERALLY SPONSORED RESEARCH AND DEVELOPMENT

This invention was made with Government support under Grant No. 0098361, awarded by the NSF. The Government has certain rights in this invention.

### BACKGROUND OF THE INVENTION

1. Field of the Invention.

(Note: This application references to various publications as indicated in the specification by reference numbers enclosed in brackets, e.g., [x]. A list of these publications ordered according to these reference numbers can be found below in the section entitled “References.” Each of these publications is incorporated in its entirety by reference herein.)

This invention relates to the field of integrated circuit interconnections, and particularly to wired inter- and intra-chip communications. A low power synchronous pulsed signaling scheme on a fully AC coupled multi-point bus interconnect for board-level chip-to-chip communication is presented.

By using a diamond data eye, the proposed single-ended or differential pulsed signaling transceiver achieves a data rate of multi-Gb/s over conventional FR4 PCB traces, which has no DC power component and dissipates much smaller I/O signaling power than the most recent memory interfaces using RSL and SSTL. By using on-chip capacitive coupling, the fully AC coupled multi-point or multi-drop bus topology with high signal integrity is proposed that minimizes the effect of inter-symbol interference (ISI) and achieves much higher 3-dB cut-off frequency than the conventional directly coupled buses.

This proposed pulsed signaling transceiver and the fully AC coupled bus topology demonstrates the methods of improving signal integrity with less signaling power dissipation. Pulsed signaling employing these techniques is suitable for use in high-speed board-level chip-to-chip communications to achieve low latency, low power, and high signal integrity.

2. Description of Related Art.

Technology scaling in CMOS chips has increased the internal clock frequency over a few tens of GHz, however, the off-chip I/O signaling speed has been scaling much more slowly. Although the CMOS high-speed serial links already entered multi-Gb/s/pin speeds by using point-to-point connections and complicated equalization techniques [1], the speed of a parallel multi-drop or multi-point bus (e.g. memory interfaces) is still in less than 2 Gb/s/pin due to the signal integrity issues in a bandwidth limited printed circuit board (PCB) environment [2]. Also, the signaling power consumption is of increasing concern. The ever-increasing demand for higher aggregate traffic rates will result in over 1 Tb/s/chip in the near future, which may consume over a few tens of W for only signaling [3], [4]. Integrating a large number of high-speed I/Os on a single chip becomes extremely challenging due to excessive complexity and power consumption.

In conventional bus-based systems with directly coupled multi-point connections, the available channel bandwidth has been primarily limited by the ISI resulting from the impedance discontinuities created by the transmission line stubs and multiple device capacitive loadings. To increase the data rate further, the trend is to replace the system bus with high-speed point-to-point I/O links [5]. However, widely parallel serial-links have overhead in terms of large area, cost, and difficulty in system scaling. Therefore, the shared bus architecture is still very attractive for low-latency, high-density and compact size board-level chip-to-chip communications with flexibility. In order to use this parallel bus topology for one more decade or even more, the problem remains how to increase the available bandwidth of a multi-point bus, how to achieve high signal integrity, and how to decrease the signaling power.

To mitigate the effect of ISI, equalization schemes [1] have been applied in directly coupled multi-point bus applications such as memory-to-processor [6] and DRAM controller-to-DRAMs [7]. However, [6] requires the ISI subtraction time, which increases the receiver latency and limits the data rate. A feed-forward equalizer [7] increases the I/O input capacitance, which may degrade the channel characteristics due to the complicated demultiplexing structure. Thus these receiver equalization schemes are not simple and cost-effective for multi-Gb/s parallel bus I/Os.

Recently, instead of using a directly coupled bus topology, which creates huge aggregate capacitance loadings on a shared line, an electromagnetically coupled memory bus was proposed to remove the connector stubs by using 1-cm zig-zag couplers [8]. Similarly, wireless AC coupling has been applied in proximity point-to-point communication for multi-chip modules (MCMs) and stacked face-to-face chips to replace the conductive mechanical junction path and increase the density of interconnections [9]-[11]. However, [8] consumes large I/O power of 40 mW/pair, since the motherboard bus is driven by conventional full-swing signaling and [9]-[11] can only be applied to extremely short (<0.5 cm) point-to-point connections. Therefore, these are unsuitable for use in high-speed parallel multi-point bus communications that require lowest I/O power dissipation.

The present invention introduces novel circuit techniques that reduce the I/O signaling power by a factor of about 10 and increase the available channel bandwidth of a multi-point bus by a factor of 2 compared to the most recent memory bus I/O schemes. By incorporating differential bidirectional pulsed signaling, the present invention achieves multi Gb/s over 10-cm printed circuit board traces with a few mW range of power for the driver and channel termination and the receiver pre-amplifier. To achieve this low power and high signal integrity in a multi-point bus, the proposed I/O scheme of the present invention employs two key circuit techniques. First, the pulsed signaling transceiver reduces the I/O power by treating the DC value of signals as redundant and using a diamond data eye. Second, capacitive coupling using on-chip metal-insulator-metal (MIM) capacitors enables a fully AC coupled multi-point bus, which minimizes the impedance discontinuities of a shared bus as well as ISI. This I/O scheme uses conventional packaging and board technologies, which is suitable for low-cost high-density front-side buses or memory buses.

As the channel frequency, PCB trace length, and device loading count increase, conventional square wave voltage-mode or current-mode signaling on a shared multi-point bus using low-swing binary or even multi-level signals becomes exceedingly difficult [2], [14]. Also, the excessive increase in I/O signaling power, simultaneous switching noise (SSN), and package/board design complexity are becoming cost and reliability issues in battery-powered mobile systems and even in power-rich multi-chip systems consisting of over a few hundreds of high-speed I/O pins. Therefore, the signal integrity and the limited available bandwidth of a periodically loaded PCB channel are of increasing concern in high-speed buses. Here, the signal integrity problem of a short distance (<30 cm) shared bus is mainly due to the impedance discontinuities created by the multiple device loadings along the channel [2], [14].

FIG. 1(a) is a schematic of a device loading model of a conventional signaling directly coupled bus, while FIG. 1(b) is a schematic of a device loading model of a pulsed signaling AC coupled bus. Shown in FIG. 1(a) is a Channel Transmission line 100, inductor Lpk, capacitor Cpk and resistor Rpk feeding into Chip 102, wherein within Chip 102, there is a Pad 104, capacitor Cp, resistor Resd, capacitor Cesd, transmitter Tx (driver) 106, receiver Rx 108 and capacitor Ca. Two diodes balance capacitor Cesd. Shown in FIG. 1(b) is a Channel Transmission line 100, inductor Lpk, capacitor Cpk and resistor Rpk feeding into Chip 102, wherein within Chip 102, there is a Pad 104, capacitor Cp, capacitor Cc, transmitter Tx 106, receiver Rx 108 and capacitor Ca.

As shown in FIG. 1(a), this multiple device loading loss on a directly coupled bus can be modeled with a series RLC network. For example, typical recent memory devices using chip scale packages have device input resistance Rin (=Rpk), inductance Lin (=Lpk), and capacitance Cin (=Cp+Cpk+Cesd+Ca), respectively, as shown in FIG. 1(a). Here the input capacitance Cin has a typical value of around 2 pF (e.g., in case of μBGA type package). It dominates the input reactive impedance Zin (=Rin+jωLin+1/jωCin, wherein j represents the imaginary unit \sqrt{−1} and ω is the frequency) and attenuation up to a few GHz.

In a pulsed signaling transceiver on an AC coupled bus, as shown in FIG. 1(b), the device input capacitance using the same package is reduced to
Cin=Cp+Cpk+(Cc Ca)/(Cc+Ca)≈0.6 pF
where Cc=0.5 pF˜0.8 pF, and Ca=0.25 pF for the driver/receiver parasitic capacitance. This is only 30% of the conventional approach. Here, the Cin is primarily determined by the net package parasitic values plus the series combination of Cc and Ca. This is because Cc decouples the driver and receiver from the I/O pin. The ESD protection circuits, which usually add up to a few pF of capacitance to a device I/O, can be eliminated because the Cc blocks the DC current path. The elimination of ESD by covering the pad with oxide is well proven in proximity communication systems where a similar AC coupling approach is used [10], [11]. Therefore, multiple device loading losses from heavy capacitive loading effect are effectively decreased by moving added poles to higher frequencies, resulting in less ISI on a shared bus, as shown in FIG. 2 and FIG. 3.

FIG. 2 is a graph of channel length (cm) vs. 3 dB frequency (GHz) that shows the simulated available channel bandwidth (3 dB cutoff frequency) of three types of double parallel terminated FR4 PCB microstrip lines used in the test board system as a function of the channel length: unloaded bus, 8-drop directly coupled bus, and 8-drop AC coupled bus. Although the unloaded 10-/20-/30-cm PCB traces have high cutoff frequencies of 6.1, 2.7, and 1.6 GHz, respectively, the channel bandwidth drops abruptly by the directly coupled device loadings. However, AC coupled buses achieve 43 to 127% higher 3 dB frequency than the directly coupled buses in the range of 10 to 30 cm. The simulation used the same WBGA package model for all cases. The package RLC parasitic values were extracted from the S parameter measurement in the frequency range of 300 KHz˜1 GHz by a vector network analyzer. The W-element RLGC transmission line model was calculated from the frequency response measurements and was used for SPICE simulation. The simulation assumes the device loading of a directly coupled bus has a total Cin of 1.8 pF, as shown in FIG. 1(a). It is comprised of Cp (0.2 pF), Cesd (0.6 pF), driver/receiver Ca (0.6+0.2 pF=0.8 pF), and 10-Ω series resistance Resd. On the contrary, the device loading of an AC coupled bus using the same WBGA has an effective Cin of 0.6 pF, as shown in FIG. 1(b), with Cp (0.2 pF), Cc (0.8 pF) and Ca (0.25 pF).

FIG. 3(a) is a graph of frequency (Hz) vs. normalized amplitude that shows the simulated channel transfer characteristics of the 10-/20-/30-cm directly coupled buses using this PCB trace with periodically mounted eight device loadings. It shows the 3 dB frequency of 1.42, 1.14, and 0.94 GHz, respectively.

FIG. 3(b) is a graph of frequency (Hz) vs. normalized amplitude that shows the simulated channel characteristics of the 10-/20-/30-cm fully AC coupled buses using the same PCB trace with the same number of loadings.

The simulation results indicate a considerably improved 3 dB frequency of 3.22, 1.95, and 1.35 GHz, respectively. This extended available bandwidth is because the input impedance Zin of the pulsed signaling transceiver is much larger than the channel characteristic impedance Zo. Also, the input capacitance Cin of the pulsed signaling transceiver is much less than that of the directly coupled bus transceivers. Therefore, the simulation results demonstrate that the fully AC coupled bus is much less sensitive to the multiple device loading losses. Moreover, the high pass transmission characteristic of an AC coupled bus rejects the low frequency noises in the transceiver system. The smaller I/O signaling power results in reduced switching noise generation on the power and ground planes. Differential signaling inherently minimizes the effect of common mode noise disturbance. The use of hysteresis in the receiver circuit also improves the noise immunity by rejecting interference noise. Consequently, although PCB skin effect and dielectric losses still exist, the signal integrity problems of a fully AC coupled bus using differential pulsed signaling become much less severe than conventional directly coupled buses using square wave signaling. Therefore, this less noisy CCBI channel with high signal-to-noise ratio makes it possible to send short pulse signal through PCB trace with less energy transmission.

The present invention focuses on power dissipation of parallel high-speed multi-point buses such as memory interfaces.

FIGS. 4(a)-(f) illustrate the schematics for the output drivers and signals for the most recent memory interfaces using a directly coupled multi-point bus topology [15]-[17] (i.e., Rambus Signaling Levels (RSL) for 1.2-Gb/s/pin Rambus DRAM (RDRAM) and Stub Series Terminated Logic (SSTL) for 800-Mb/s/pin DDR SDRAM) and the proposed 1-Gb/s/pair capacitive coupled pulsed signaling bus interface (CCBI) of the present invention, respectively.

In addition, the following table compares the I/O signaling power and energy efficiency of RSL, SSTL and CCBI.

| | RSL | SSTL | CCBI |
|---|---|---|---|
| | (1.2 Gb/s) | (800 Mb/s) | (1 Gb/s) |
| Output driver | Open Drain | Push Pull | Push Pull |
| type | | | |
| Termination | Single Parallel | Double Parallel | Double Parallel |
| I/O Frequency | 600 MHz | 400 MHz | 500 MHz |
| | (1.2 Gb/s) | (800 Mb/s) | (1 Gb/s) |
| Signal Swing | Square Wave | Square Wave | Pulse (Diamond) |
| Driver Power | 28.6 mW | 7.7 mW | 1.3 mW |
| Termination | 22.9 mW | 9.8 mW | 0.15 mW |
| Power | | | |
| Total Power | 51.5 mW (worst) | 17.5 mW | 1.45 mW × 2 = 2.9 |
| | 51.5 mW/2 = | | mW |
| | 25.75 mW (avg.) | | |
| Energy | 43 pJ/bit (worst) | 21.9 pJ/bit | 2.9 pJ/bit |
| Efficiency | 21.5 pJ/bit (avg.) | | |

Currently in the market, the RDRAM and DDR SDRAM are now providing 1066 Mb/s/pin and 667 Mb/s/pin, respectively. The present invention compares, however, with their future highest data rate. The DDR-I and DDR-II use different power supply of 2.5 and 1.8 V, respectively, but both use basically the same SSTL signaling scheme except for the use of an on-die termination in DDR-II [17].

The table set forth above focuses on the power dissipation of the final stage output driver and the channel termination. It is assumed the signal swing of the RSL and SSTL are 0.8 V and 0.7 V, respectively. To simplify the comparison, this table does not consider the other sources of signaling power consumption: pre-driver power (the power required to drive the output driver) and receiver power. The pre-driver of the conventional schemes usually consumes very large power to drive the heavy final-stage output driver with a fast slew rate. The receiver power is usually much smaller than the driver power in memory interfaces.

The 1.2-Gb/s RSL dissipates 28.6 mW (1V×28.6 mA) for the open drain current-mode output driver and 22.9 mW ((0.8V)²/28Ω) for the termination with a 28-Ω resistor for a 0.8-V channel swing by sinking 28.6 mA per line. The total average power is 25.75 mW for data patterns with a balanced stream of 1's and 0's, which means the worst-case power dissipation could be doubled to 51.5 mW. The SSTL consumes 7.7 mW (0.55V×14 mA) for the push-pull type output driver, 4.9 mW ((0.35V)²/25Ω) for the channel termination with two parallel 50-Ω resistors (effective Rt=25Ω), and 4.9 mW ((0.35V)²/25Ω) for the series termination with a 25-Ω resistor for a 0.7-V swing by sinking 14 mA. The total power dissipation of SSTL is 17.5 mW for a data rate of 800 Mb/s.

In pulsed signaling, the single output driver dissipates a maximum dynamic power of 1.3 mW (CcVdd²f=0.8 pF(1.8V)²/2ns) to drive the Cc of 0.8 pF with a rail-to-rail swing. Since the channel has no DC current consumption, the channel termination power for the two parallel 50-Ω resistors is only 0.15 mW. Thus, the total power dissipation is reduced to only 2.9 mW/pair at 500 MHz for a data rate of 1-Gb/s/pair. By calculating the energy per bit (or the power for a specific data rate), the energy efficiency of these bus I/O schemes can be compared. The energy to transfer one bit data can be defined as
Energy/bit=Power/data rate.

The SSTL and RSL dissipate 21.9 pJ/bit and 21.5 pJ/bit, respectively.

However, pulsed signaling consumes only a maximum of 2.9 pJ/bit. This shows that pulsed signaling is 7.5 times more energy efficient than the above most recent memory interface schemes. Consequently, the present invention provides significant improvements over prior technology.

### SUMMARY OF THE INVENTION

The present invention discloses novel circuit techniques [12] that reduce the I/O signaling power by a factor of 7.5 and increase the available channel bandwidth of a multi-point bus by a factor of 2 compared to the most recent memory bus I/O schemes. The proposed CCBI scheme, which incorporates differential bidirectional pulsed signaling, achieves 1 Gb/s over 10-cm printed circuit board traces with 2.9 mW of power for the driver and channel termination and 2.7 mW for the receiver pre-amplifier. To achieve this low power and high signal integrity in a multi-point bus, the I/O scheme employs two key circuit techniques. First, the pulsed signaling transceiver reduces the I/O power by treating the DC value of signals as redundant and using a diamond data eye. Second, capacitive coupling using on-chip MIM capacitors enables a fully AC coupled multi-point bus, which minimizes the impedance discontinuities of a shared bus as well as ISI. This I/O scheme uses conventional packaging and board technologies, which is suitable for low-cost high-density front-side buses or memory buses.

### BRIEF DESCRIPTION OF THE DRAWINGS

FIG. 1(a) is a device loading model of a conventional signaling directly coupled bus and FIG. 1(a) is a device loading model of a pulsed signaling AC coupled bus.

FIG. 2 is a graph of the simulated available bus channel (FR4 PCB) bandwidth with unloaded and 8 device loadings.

FIG. 3(a) is a graph of the simulated channel transfer characteristics of the 8-drop directly coupled bus, and FIG. 3(b) is a graph of the simulated channel transfer characteristics of the 8-drop AC coupled bus.

FIGS. 4(a)-(f) illustrate the output driver schematics and signal types for RSL, SSTL and CCBI, respectively.

FIG. 5(a) illustrates the board-level structure of pulsed signaling on a fully AC coupled bus, and FIG. 5(b) illustrates the detailed synchronous system architecture of pulsed signaling on a fully AC coupled bus.

FIG. 6(a) is a modeling of pulsed signaling on a PCB transmission line, FIG. 6(b) is an equivalent differentiating circuit with a small RC time constant τ, and FIG. 6(c) is a graph of the transient response of an equivalent circuit.

FIG. 7(a) is a schematic of a Pulsed Signaling Transmitter circuit, FIG. 7(b) is a schematic of an output driver, and FIG. 7(c) is a transmitter timing diagram of synchronous pulsed signaling.

FIG. 8(a) is a schematic of a Pulsed Signaling Receiver circuit, FIG. 8(b) is schematic of an amplifier, and FIG. 8(c) is a receiver timing diagram of synchronous pulsed signaling.

FIG. 9 is a 1-Gb/s Diamond eye diagram at the receiver (pre-amplifier input, point E) on a FR4 PCB trace.

FIG. 10 is the simulated 2-Gb/s/pair pulsed signaling over a 10-cm AC coupled bus.

FIG. 11 is a schematic of a multi-point AC coupled bus interconnect.

FIG. 12 is a schematic of a point-to-point AC coupled interconnect.

FIG. 13 is a schematic of an on-chip AC coupled interconnect.

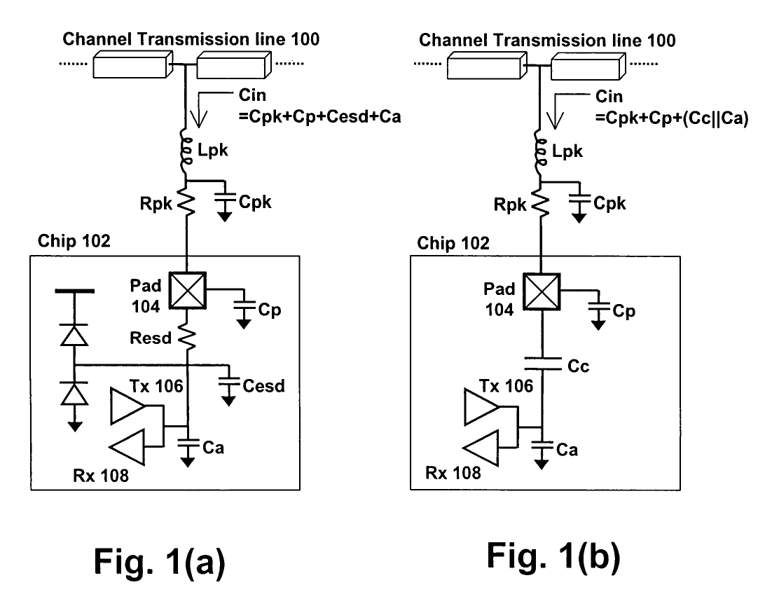

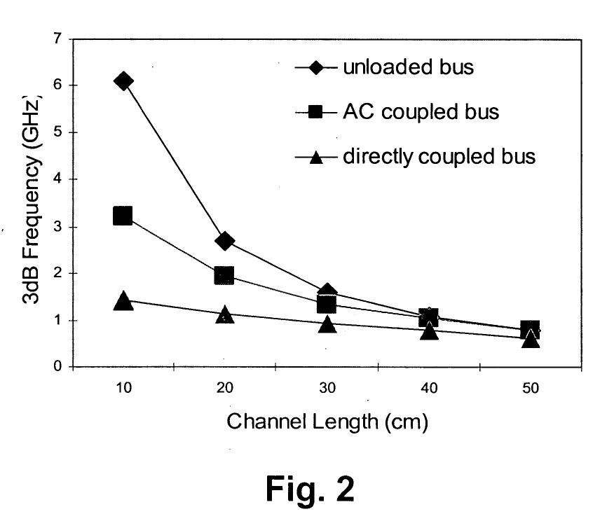

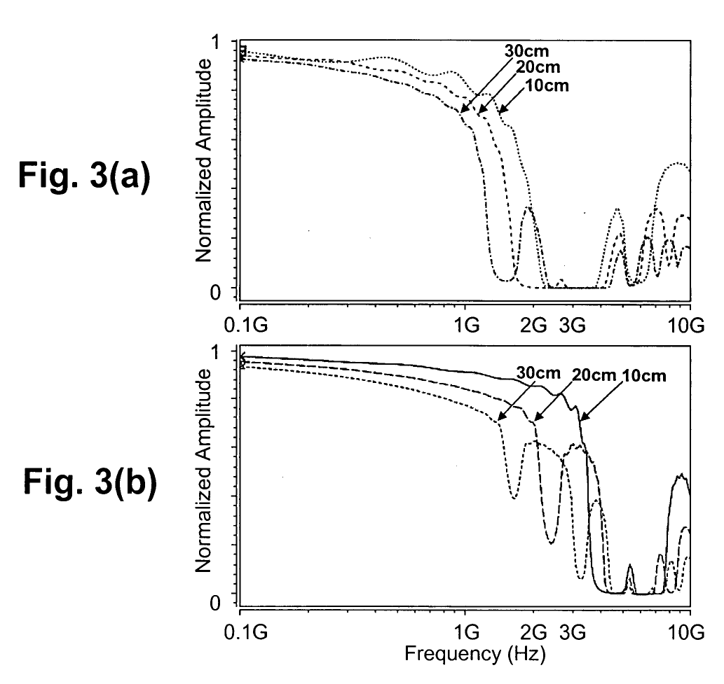

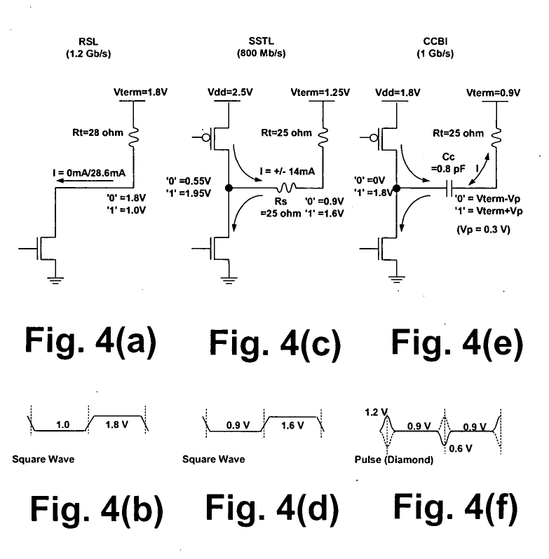

### DETAILED DESCRIPTION

In the following description of a preferred embodiment, reference is made to the accompanying drawings, which form a part hereof, and in which is shown by way of illustration a specific embodiment in which the invention may be practiced. It is to be understood that other embodiments may be utilized and structural changes may be made without departing from the scope of the present invention.

Overview

A new capacitive coupled pulsed signaling bus interface (CCBI) has been developed as an effective solution to reduce the I/O signaling power and improve the signal integrity in low-cost multi-point or multi-drop or point-to-point parallel bus systems. A single ended or differential synchronous pulsed signaling I/O technology utilizing on-chip capacitive coupling for low power, high bandwidth, parallel bus links (such as a system bus or a main memory bus) has been proposed.

Capacitive Coupled Pulsed Signaling Bus Interface (CCBI) System Architecture and Interconnect Modeling

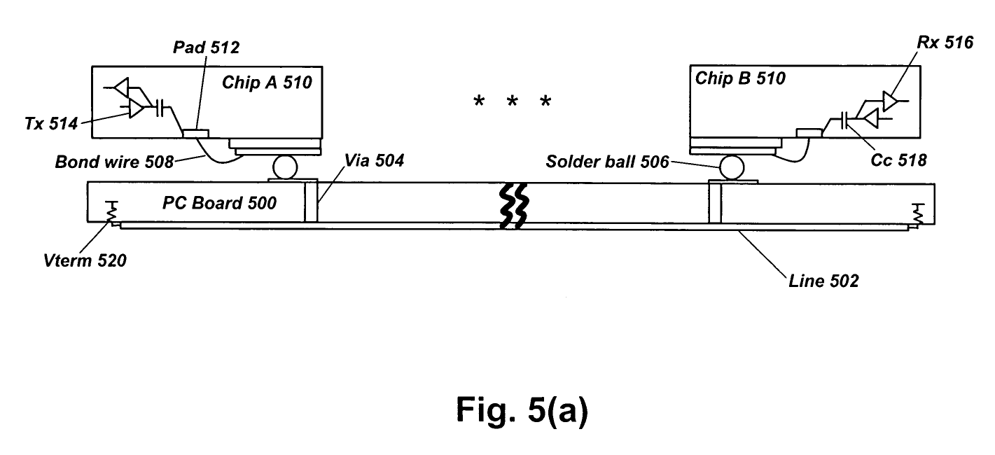

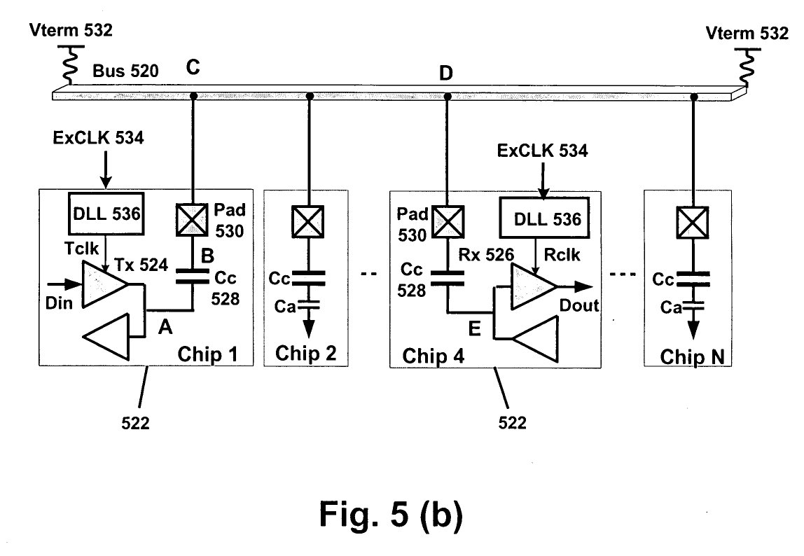

FIG. 5(a) illustrates the board-level structure of pulsed signaling on a fully AC coupled bus. Included in this structure is a PC board 500, microstrip line 502, vias 504, solder balls 506, bond wires 508, chips 510, pads 512, transmitters Tx 514, receivers Rx 516, capacitors Cc 518 and terminating resistors Vterm 520.

In this embodiment of the proposed pulsed signaling system [12], the chip scale packages (CSPs) 510, which may be wirebond ball grid arrays (WBGA) or micro ball grid arrays (μBGA), are mounted in a chip-on-board fashion on a conventional PC board 500 trace. On-chip MIM capacitor Cc 518, which is formed between the two metal plates, decouples the transmitter Tx 514 and receiver Rx 516 circuits from the I/O pad 512, and therefore enables a reliable fully AC coupled multi-point bus.

FIG. 5(b) illustrates the detailed synchronous system architecture of pulsed signaling on a fully AC coupled bus (which is single-ended for simplicity). Included in this architecture is a bus transmission line 520, chip packages 522, transmitters Tx 524, receivers Rx 526, and capacitors Cc 528.

In FIG. 5(b), the chip packages 522 are mounted on a bus transmission line 520. The transmitter Tx 524 of Chip 1 522 and the receiver Rx 526 of Chip 4 522 are coupled to the bus transmission line 520 through an on-chip coupling capacitor Cc 528 and Pad 530 at points C and D, respectively. Both ends of the bus transmission line 520 are parallel terminated by impedance-matching resistors 532 with Vterm=Vdd/2. Source synchronous clocking (with ExCLK 534: one round trip or two forwarded clocks) is used, with a delay looked loop (DLL) 536, to remove the skew between the clock and the pulse signals. On-chip MIM capacitor Cc 528, which is formed between the two metal plates, decouples the transmitter Tx 524 and receiver Rx 526 circuits from the I/O pads 530, and therefore enables a reliable fully AC coupled multi-point bus.

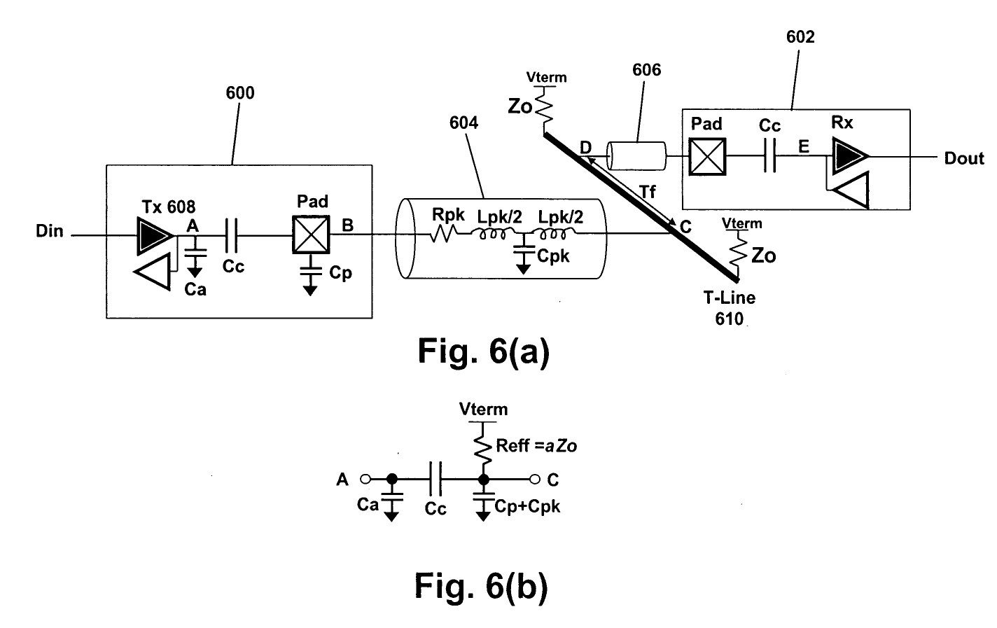

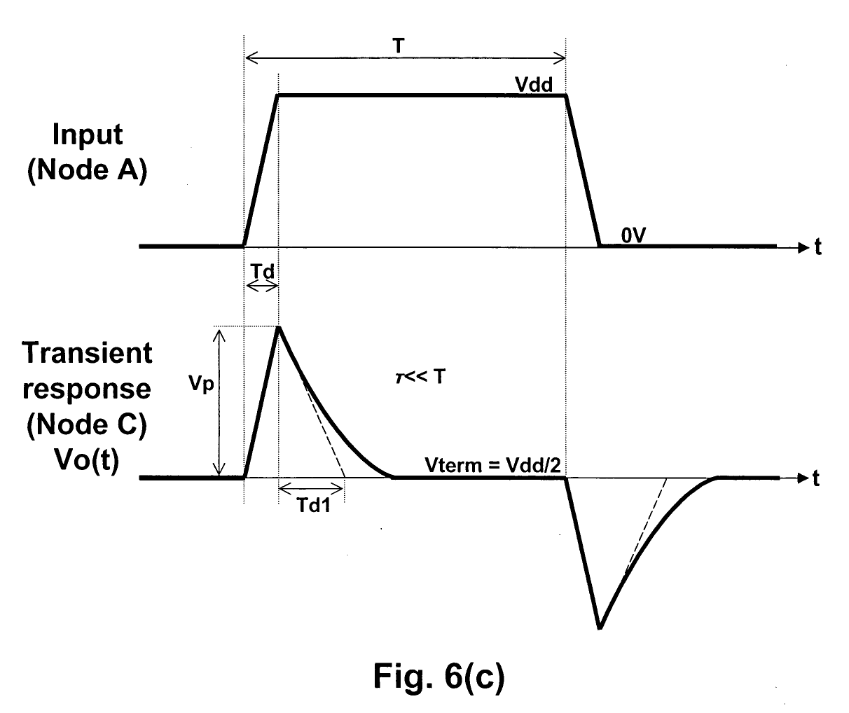

To ensure reliable pulsed signaling over 1 Gb/s, the multi-point interconnects and device package loading models need to be accurate up to a few GHz. FIG. 6(a) is a modeling of single-ended pulsed signaling on a PCB transmission line, which includes a transmitter chip 600 and receiver chip 602, wherein 604 and 606 represent the package parasitics. Since the loss of the MIM capacitor, the resistance and the inductance of the metal plates, and the parasitic capacitance between the metal and substrate are negligible in the frequency range of operation, a lumped capacitance model can be used for Cc.

As shown in FIG. 6(b), the equivalent I/O circuit path serves as a differentiating circuit or a single-time-constant high-pass circuit with a transfer function
T(s)=(C_{c}/C_{eff})sR_{eff}C_{eff}/(1+sR_{eff}C_{eff})
where C_{eff}=C_{c}+Cₚ+Cₚₖ and a time constant τ=R_{eff}C_{eff}. Cₚ and Cₚₖ are parasitic capacitances for the bonding pad and package pin, respectively.

This can be used to analyze and define the pulse signal characteristics (e.g., eye width and amplitude) on the PCB channel. FIG. 6(c) shows the transient response of this equivalent circuit, which generates a diamond data eye. This high-pass circuit transmits the transient part of the input data. However, the DC signal component is blocked. A step input voltage VA on node A by the full-swing output driver (transmitter Tx 608 of FIG. 6(a)) results in a transient on node C, transforming a square wave binary input into a short pulse wave on the channel with polarity and amplitude (Vp) of about
Vp=Reff×Ic=αZo×Cc×dVA/dt
where Reff=Zo/2+Rpk+2πf×Lpk=αZo. For example, α=0.6˜0.7 in the frequency (f) range of 500 MHz ˜1 GHz. Here, the induced small current Ic=Cc×dVA/dt on the channel is determined by the edge speed (dt=Td) of the output driver. The transient output wave form Vo(t) decays exponentially,
Vo(t)=Vpexp(−t/τ)+Vterm
toward the termination voltage Vterm=Vdd/2 with a very small time constant τ,
τ=Reff×Ceff=αZo(Cc+Cp+Cpk)
where Ceff=Cc+Cp+Cpk. If the ESD capacitance (Cesd) is considered, Ceff becomes Cc+Cp+Cpk+Cesd. It takes rise or fall time of Td1=ln(9)τ=2.2τ to get from the 10% to the 90% point. Then, the pulse width (Tw) on the PCB channel is approximately determined by
Tw=Td+Td1
where usually Td1 is dominant and Tw <<T. T is the data period. So, the Vp and Tw of the diamond data eye is controlled by choosing the proper values of Cc and Td.

To ensure low energy transmission in this pulsed signaling, the total signal attenuation including PCB channel and package loss need to be analyzed and should be in the range of design tolerance. In FIG. 6(a), the first signal loss occurs through the package pin parasitic of the transmitter output path, from point B to C, including bonding wire, solder bump and via, which is a kind of a band-limiting conductive connection. Similarly at the receiver path, there is package and capacitor loss from point D to E. Low-parasitic chip scale packages are preferred to minimize this attenuation. However, the dominant signal loss occurs through the multi-point bus and depends on the channel length and the mounted device count. After the propagation delay of Tf, the pulse arrives at the receiver chip 602 with reduced amplitude due to the channel losses (skin effect and dielectric loss), dispersions and reflections on the transmission line. To achieve better noise immunity, by rejecting common-mode disturbances as well as crosstalk from other noise sources, shielded differential signal lines can be used. Also, the capacitor area can be reduced by using thin dielectric layers or high dielectric constant materials or by forming the capacitor under the bonding pad.

Transceiver Architecture and Timing Diagram The pulsed signaling transceiver utilizes AC coupling and thus has no DC current component on the channel. It also eliminates the DC balancing problems of the conventional AC coupling schemes [9], [13] without using data encoding or feedback schemes since the transient pulse decays rapidly toward the termination voltage as shown in FIG. 6(c), which is a graph of the transient response of an equivalent circuit.

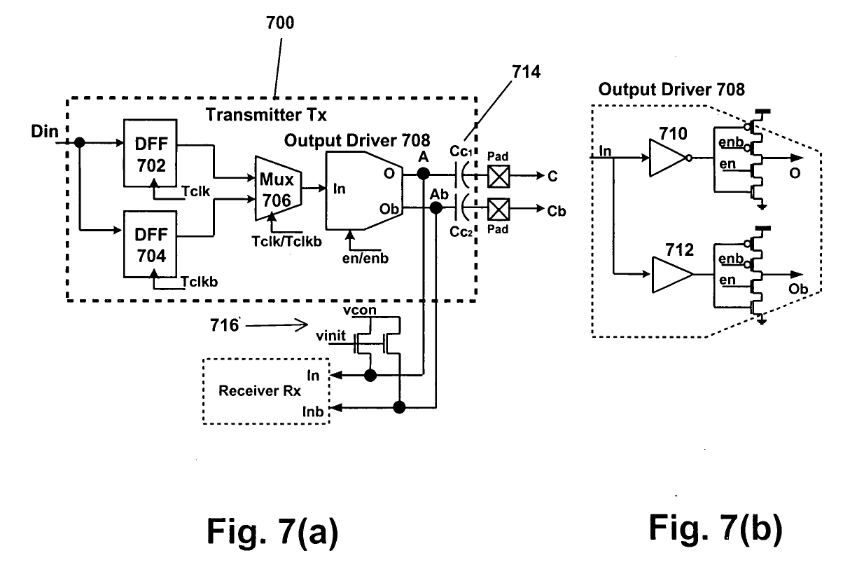

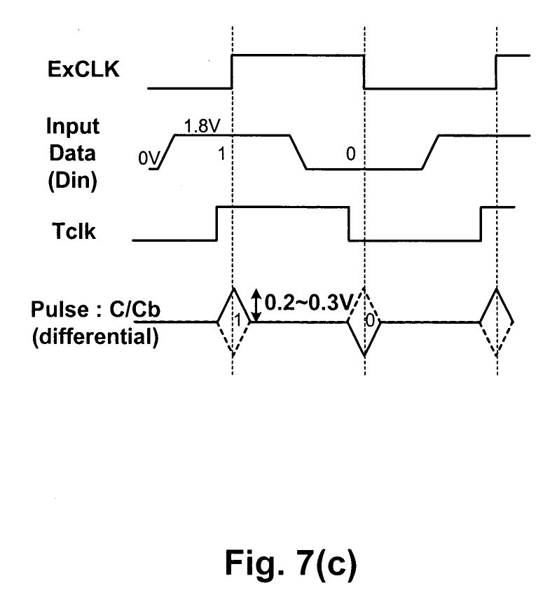

FIG. 7(a) is a schematic of a Pulsed Signaling Transmitter circuit 700, which includes D flip-flops 702 and 704, a mux 706, and an output driver 708. FIG. 7(b) further illustrates the differential output driver 708, which is comprised of small tri-state buffers 710 and 712 with full-swing outputs (O/Ob) and a controlled slew rate. When it drives the node A of Cc1 714, a small current pulse is induced on the other side of Cc1 714 and converted to a short voltage pulse with polarity and a peak amplitude of about 0.2˜0.3 V. As shown in the timing diagram of FIG. 7(c), the pulses are synchronized and transferred in parallel with the external clock (ExCLK). This occurs without board level skew by using the Tclk/Tclkb generated from the transmit DLL. When the output driver 708 is not active, it is turned-off (en/enb=low/high) and A/Ab nodes are precharged and equalized by signal Vinit of transistors 716 to a voltage Vcon=Vterm to initiate a common mode. The required size of the output driver 708 to drive the Cc of 0.5 ˜0.8 pF is much smaller than that of conventional square wave signaling output drivers, resulting in smaller parasitic capacitance Ca at the output node A/Ab and a reduced power dissipation. Unlike the transmitters of the directly coupled buses consuming both large DC and AC power and introducing large simultaneous switching Ldi/dt noise, this pulsed signaling transmitter 700 consumes only very small AC power. Also, the low frequency system noise is filtered out by the high pass transmission characteristic of an AC coupled transmitter path. All of these make it possible for the pulsed signaling transmitter 700 to put less energy into the channel and for the receiver to operate with moderate power dissipation.

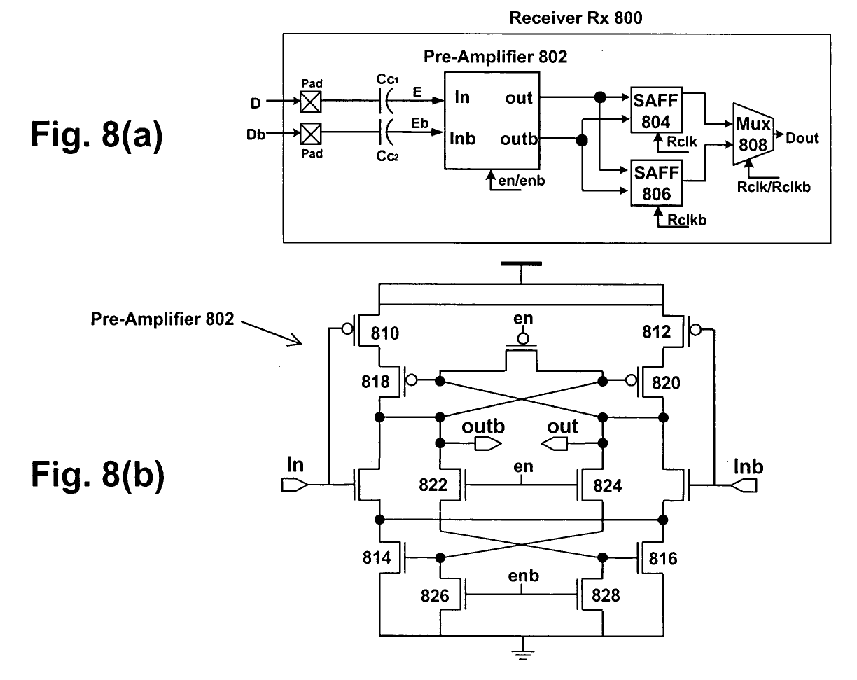

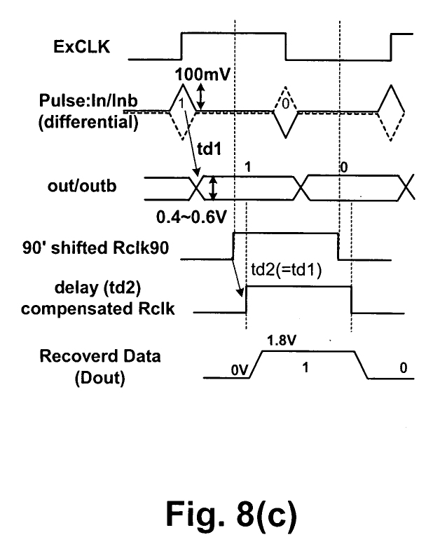

FIG. 8(a) is a schematic of a Pulsed Signaling Receiver circuit 800, which includes a differential static pre-amplifier 802 and two typical sense amplifier based flip-flops (SAFFs) 804 and 806, and a mux 808. FIG. 8(b) is a schematic that further illustrates the differential static pre-amplifier 802. Since the incoming signal at node E/Eb is a short pulse with small amplitude, a static cross-coupled pre-amplifier 802 is required to sense and latch it. This differential pre-amplifier 802, which exhibits hysteresis, has the built-in ability to filter out the incoming noise from imperfect termination and common mode disturbances such as ground bouncing or power supply drop. It consists of input stage transistors 810, 812, 814 and 816. The cascode transistors 818 and 820 are cross-coupled each other, as are the cascode transistors 814 and 816, and transistors 822, 824, 826 and 828 are used to remove the standby current dissipation.

Also, the crosstalk noise from adjacent data lines can be eliminated by using extra shielding lines. The synchronous timing diagram of the receiver is shown in FIG. 8(c). The pulse signal arrives at the receiver in parallel with the ExCLK, and is recovered with a data-to-q delay of tdl. The center of this data (out/outb) window is phase locked with the Rclk, which is delay compensated (td2=td1). The 90 degree shifted clock (Rclk90) is generated from the receiver DLL by synchronizing with the ExCLK. The differential output (out/outb) is amplified and latched by the demultiplexing SAFFs 804 and 806. The power consumption of the differential pre-amplifier 802 is comparable with that of typical high-speed DRAM receivers with three-stage (pre-amplifier, sense-amp, and latch) structures [16]. The static power can be minimized by switching it off (en=low) when the receiver is not active.

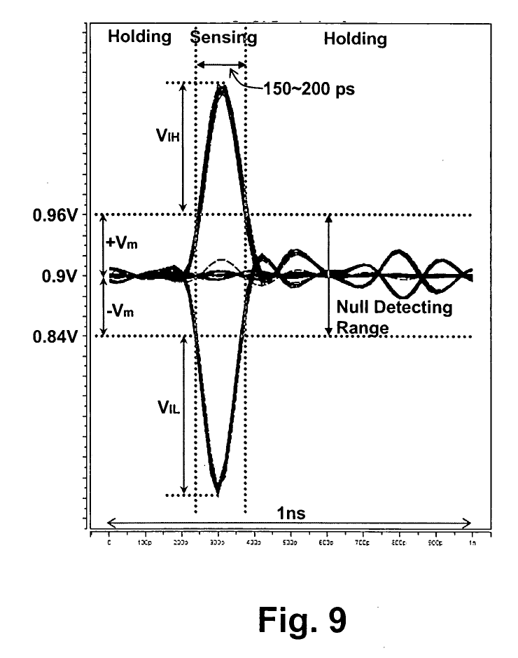

FIG. 9 shows the simulated diamond eye diagram of the pulse signals (data rate with a 1 Gb/s for example) at the pre-amplifier input (point E) of the receiver chip after passing through a PCB trace. The noise margin for VIH and VIL and the sensing and holding window of the pre-amplifier 802 are defined here. In the null detecting range (between Vterm-Vm and Vterm+Vm where, for example, Vterm=0.9V and Vm=60mV), the pre-amplifier 802 maintains the previous value with hysteresis characteristic. This can filter out the noise from the mismatched channel termination and it enables the receiver to be less sensitive to internal chip noise. The required minimum pulse amplitudes for the logical thresholds of the sensing operation, defined by VIH (above Vterm+Vm) and VIL (below Vterm−Vm), must be kept larger than the null detecting range.

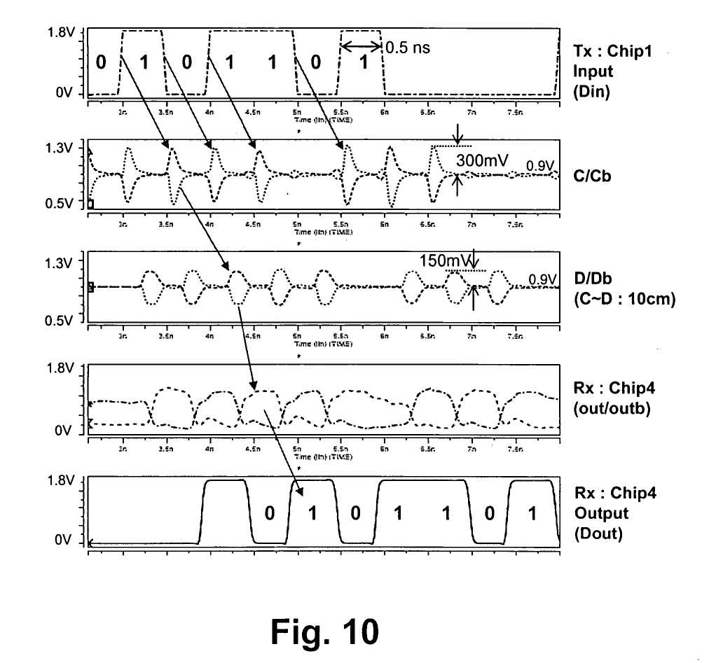

FIG. 10 shows the simulated 2-Gbps/pair pulsed signaling using 0.8 pF Cc over a 10-cm FR4 differential PCB trace from C to D as depicted in FIG. 6(a). When the transmitter Chip 1 sends out 1-GHz binary data Din, it is converted to short pulses with Vp of about +/−300 mV and Tw of about 100 ps at point C/Cb. Then, the transmitted pulses get attenuated and wider with Vp of about +/−150 mV and Tw of about 200 ps at point D/Db. These are then recovered at the receiver Chip 4. Since there is no need for coding/decoding of input/output signals or feedback schemes, the transmitter and receiver have no latency overhead compared to the conventional square wave signaling transceivers of high-speed DRAMs where low latency is very important for system performance.

Novel Aspects

The following identifies the novel aspects of the present invention.

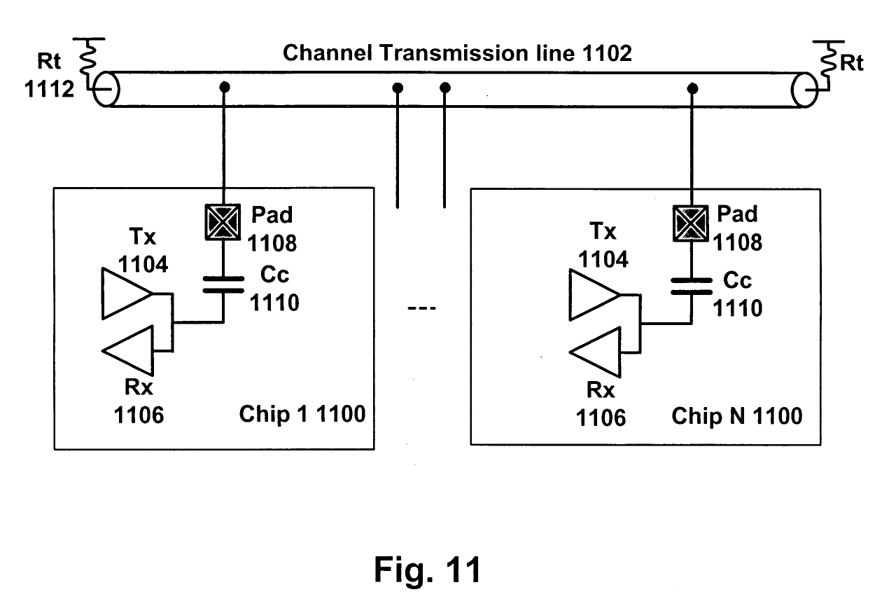

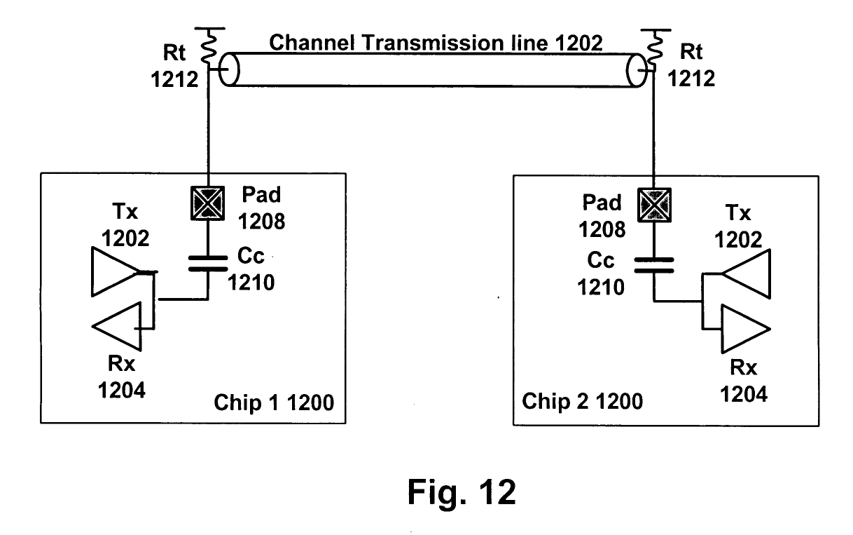

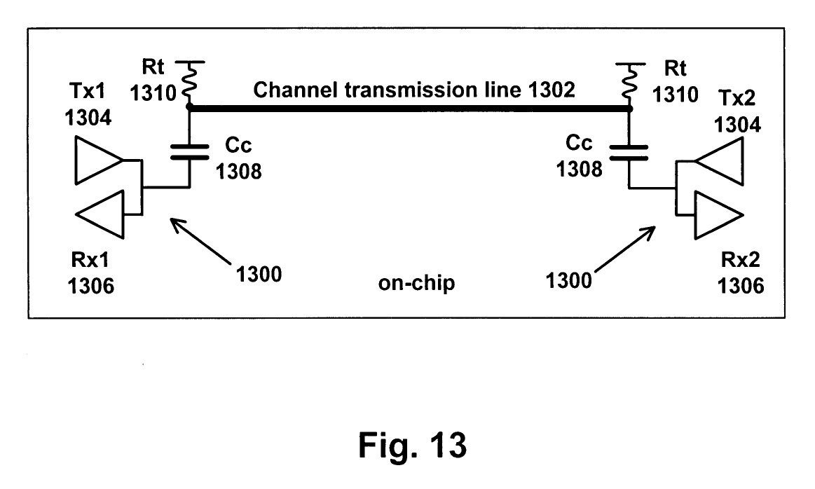

1. Capacitive coupled pulsed signaling bus interface (CCBI) system architecture (FIGS. 5(a) and (b), FIGS. 6(a), (b) and (c), FIG. 11, FIG. 12, and FIG. 13).

The methods and architectures to enable a fully AC coupled bus interconnect that increases the available channel bandwidth with higher signal integrity.

The methods and architectures to reduce the I/O signaling power (including output driver and channel termination) by using pulsed signaling on a fully AC coupled bus.

The signaling technology which utilizes single-ended or differential pulsed signaling with a diamond data eye that has a small time constant.

This technology can be applied to multi-point, multi-drop, or point-to-point interconnect.

The transmitter path of this CCBI enables a high-pass filter or a differentiator circuit network, which generates a small triangle pulse on the channel.

A) The synchronous, multi-point, bidirectional, pulsed signaling system architecture (single-ended for simplicity) of FIGS. 5(a) and (b).

As noted above, the chip packages 522 are mounted on a bus transmission line 520. The transmitter Tx 524 of Chip 1 522 and the receiver Rx 526 of Chip 4 522 are coupled to the bus transmission line 520 through an on-chip coupling Cc 528 and Pad 530 at point C and D, respectively. Both ends of the bus transmission line 620 are parallel terminated by the impedance matching resistors 532 with Vterm=Vdd/2. Source synchronous clocking (with ExCLK 534: one round trip or two forwarded clocks) is used, with a delay looked loop (DLL) 536, to remove the skew between the clock and the pulse signals. On-chip MIM capacitor Cc 528, which is formed between the two metal plates, decouples the transmitter Tx 524 and receiver Rx 526 circuits from the I/O Pad 530, and therefore enables a reliable fully AC coupled multi-point bus.

B) The architecture of the equivalent (single-ended) pulsed signaling interconnect model of FIG. 6(a), the equivalent model of FIG. 6(b), and the graph of the transient response of an equivalent circuit of FIG. 6(c).

As noted above, FIG. 6(a) is a modeling of single-ended pulsed signaling on a PCB transmission line, which includes a transmitter chip 600 and receiver chip 602, wherein 604 and 606 represent the package parasitics. The equivalent I/O circuit serves as a differentiating circuit or a high-pass filter with a small time constant Tas shown in FIG. 6(b). FIG. 6(c) shows the transient response of this equivalent circuit, which generates a diamond data eye. This high-pass circuit transmits the transient part of the input data. However, the DC signal component is blocked. A step input voltage VA on node A by the full-swing output driver (transmitter Tx 608 of FIG. 6(a)) results in a transient on node C, transforming a square wave binary input into a short pulse wave on the channel with polarity and amplitude Vp as explained above.

It takes rise or fall time of Td1 get from the 10% to the 90% point. Then, the pulse width (Tw) on the PCB channel transmission line (T-Line) 610 is approximately determined by Tw=Td+Td1, where usually Td1 is dominant and Tw<<T. T is the data period. So, the Vp and Tw of the diamond data eye is controlled by choosing the proper values of Cc and Td.

After the propagation delay of Tf, the pulse arrives at the receiver chip 602 with reduced amplitude due to the channel losses (skin effect and dielectric loss), dispersions and reflections on the transmission line. To achieve better noise immunity, by rejecting common-mode disturbances as well as crosstalk from other noise sources, shielded differential signal lines can be used. Also, the capacitor area can be reduced by using thin dielectric layers or high dielectric constant materials or by forming the capacitor under the bonding pad.

C) FIG. 11: Multi-point AC coupled bus interconnect.

The architectures to enable a fully AC coupled multi-point bus interconnect that increases the available channel bandwidth with higher signal integrity and also reduces the signaling power consumption.

FIG. 11 is a schematic of a multi-point AC coupled bus interconnect. In FIG. 11, the multiple pulsed signaling transceiver chips 1100 are coupled on a terminated channel (PCB or cable line) 1102. In the transceiver chips 1100, the transmitter Tx 1104 and receiver Rx 1106 are AC coupled to the I/O Pad 1108 through the on-chip MIM capacitor Cc 1110. The input node of the receiver Rx 1106 can be terminated with a desired common mode voltage by using proper resisters or transistors, although it is not shown in this figure. This enables a fully AC coupled multi-point bus interconnect. Moreover, both ends of the bus 1102 are parallel terminated by the impedance matching resistors 1112. This unique interconnect architecture makes a small triangle pulses to transfer data on the channel, which makes a diamond data eye unlike the conventional directly coupled buses using a square wave data eye.

D) FIG. 12: Point-to-pointAC coupled interconnect.

The architectures to enable a fully AC coupled point-to-point interconnect that increases the available channel bandwidth with higher signal integrity and reduces the signaling power consumption.

FIG. 12 is a schematic of a point-to-point AC coupled interconnect. The two pulsed signaling transceiver chips 1200 are coupled on a terminated channel (PCB or cable line) 1202. In the transceiver chip 1200, the transmitter Tx 1202 and receiver Rx 1206 are AC coupled to the I/O pad 1208 through the on-chip MIM capacitor Cc 1210. The input node of the receiver Rx 1204 can be terminated with a desired common mode voltage by using proper resisters or transistors, although it's not shown in this figure. This enables a fully AC coupled point-to-point interconnect. Moreover, both ends of the bus 1202 are parallel terminated by the impedance matching resistors 1212.

E) FIG. 13: On-chip AC coupled interconnect.

The architectures to enable an on-chip AC coupled interconnect that reduces the signaling power consumption.

FIG. 13 is a schematic of an on-chip AC coupled interconnect. The two pulsed signaling transceivers 1300 are AC coupled on a terminated channel 1302. The transmitters Tx1 and Tx2 1304 and receivers Rx1 and Rx2 1306 are AC coupled to the channel 1302 through the capacitors Cc 1308. The input node of the receivers Rx1, Rx2 can be terminated with a desired common mode voltage by using proper resisters or transistors, although it is not shown in this figure. The capacitors Cc 1308 can be implemented by on-chip MIM capacitors or metal-oxide-silicon (MOS) transistor capacitors. The channel terminators 1310 can be implemented by resistors or MOS transistors.

2. Transceiver architecture and a timing diagram (FIGS. 7(a), (b) and (c), FIGS. 8(a), (b) and (c)).

The architecture of the pulsed signaling transceiver which utilizes AC coupling and thus has no dissipation of DC current component on the channel.

This transceiver architecture and the using of terminated channel eliminate the DC balancing problems of the conventional AC coupling schemes [9], [13] without using data encoding or feedback schemes since the transient pulse decays rapidly toward the termination voltage as shown in FIG. 6(c).

A) The transmitter architecture which generates pulse signal on the channel.

As noted above, FIG. 7(a) shows the pulsed signaling transmitter circuit 700, which is comprised of D flip-flops 702 and 704, a mux 706, and an output driver 708. FIG. 7(b) shows the differential output driver 708, which is comprised of small tri-state buffers 710 and 712 with full-swing outputs (O/Ob) and a controlled slew rate. When it drives the node A of Cc1 714, a small current pulse is induced on the other side of Cc1 714 and converted to a short voltage pulse with polarity and a peak amplitude of about 0.2˜0.3 V. As shown in the timing diagram of FIG. 7(c), the pulses are synchronized and transferred in parallel with the external clock (ExCLK). This occurs without board level skew by using the TcIk/TcIkb generated from the transmit DLL. When the output driver 708 is not active, it is turned-off (en/enb=low/high) and A/Ab nodes are precharged and equalized by signal Vinit of transistors 716 to a voltage Vcon=Vterm to initiate a common mode. The required size of the output driver 708 to drive the Cc is much smaller than that of the conventional square wave signaling output drivers, resulting in smaller parasitic capacitance Ca at the output node A/Ab and a reduced power dissipation. Unlike the transmitters of the directly coupled buses consuming both large DC and AC power and introducing large simultaneous switching Ldi/dt noise, this pulsed signaling transmitter consumes only very small AC power. Also, the low frequency system noise is filtered out by the high pass transmission characteristic of an AC coupled transmitter path. All of these make it possible for the pulsed signaling transmitter to put less energy into the channel and for the receiver to operate with moderate power dissipation.

B) The Receiver Architecture

As noted above, FIG. 8(a) shows the pulsed signaling receiver circuit 800, which includes a differential static pre-amplifier 802 and two typical sense amplifier based flip-flops (SAFFs) 804 and 806, and a mux 808. FIG. 8(b) further illustrates the differential static pre-amplifier 802.

Since the incoming signal at node E/Eb is a short pulse with small amplitude, a static cross-coupled pre-amplifier 802is required to sense and latch it. This differential pre-amplifier 802, which exhibits hysteresis, has the built-in ability to suppress the incoming noise from imperfect termination and common mode disturbances such as ground bouncing or power supply drop. It is comprised of input stage transistors 810, 812, 814 and 816. The cascode transistors 818 and 820 are cross-coupled each other. The cascode transistors 814 and 816 are cross-coupled each other. Transistors 822, 824, 826 and 828 are used to remove the standby current dissipation.

The synchronous timing diagram of the receiver is shown in FIG. 8(c). The pulse signal arrives at the receiver in parallel with the ExCLK, and is recovered with a data-to-q delay of td1. The center of this data (out/outb) window is phase locked with the Rclk, which is delay compensated (td2=td1). The 90 degree shifted clock (Rclk90) is generated from the receive DLL by synchronizing with the ExCLK. The differential output (out/outb) is amplified and latched by the demultiplexing SAFFs 804 and 806. The static power can be removed by switching it off (en=low) when the receiver is not active.

### REFERENCES

The following references are incorporated by reference herein:

[1] V. Stojanovic, M. Horowitz, “Modeling and Analysis of High-Speed Links,” in Proc. IEEE Custom Integrated Circuits Conf., September 2003, pp. 589-594.

[2] J. L. Zerbe, P. S. Chau, C.W. Werner, T. P. Thrush, H. J. Liaw, B. W. Garlepp, K. S. Donnelly, “1.6 Gb/s/pin 4-PAM Signaling and Circuits for a Multidrop Bus,” IEEE J. Solid-State Circuits, pp. 752-760, May 2001.

[3] K. J. Wong, H. Hatamkhani, M. Mansuri, C. K. Yang, “A 27-mW 3.6-Gb/s I/O Transceiver,” IEEE J. Solid-State Circuits, pp. 602-612, April 2004.

[4] M. E. Lee, W. J. Dally, P. Chiang, “Low-PowerArea-Efficient High-Speed I/O Circuit Techniques,” IEEE J. Solid-State Circuits, pp. 1591-1599, November 2000.

[5] N. Rohrer, M. Canada, E. Cohen, M. Ringler, M. Mafield, P. Sandon, P. Kartschoke, J. Heaslip, J. Allen, P. Mccormick, T. Pfluger, J. Zimmerman, C. Lichtenau, T. Werner, G. Salem, M. Ross, D. Appenzeller, D. Thygesen, “PowerPC 970 in 130 nm and 90 nm Technologies,” in IEEE Int. Solid-State Circuits Conf. Dig. Tech. Papers, February 2004, pp. 68-69.

[6] H. Tamura, M. Saito, K. Gotoh, S. Wakayama, J. Ogawa, Y. Kato, M. Taguchi, T. Imamura, “Partial Response Detection Technique for Driver Power Reduction in High-Speed Memory-to-Processor Communications,” in IEEE Int. Solid-State Circuits Conf. Dig. Tech. Papers, February 1997, pp. 342-343.

[7] J. Sim, J. Nam, Y. Sohn, H. Park, C. Kim, S. Cho, “A CMOS Transceiver for DRAM Bus System With a Demultiplexed Equalization Scheme,” IEEE J. Solid-State Circuits, pp. 245-250, February 2002.

[8] T. Simon, R. Amirtharajah, J. R. Benham, J. L. Critchlow, T. F. Knight Jr., “A 1.6 Gb/s/pair Electromagnetically Coupled Multidrop Bus Using Modulated Signaling,” in IEEE Int. Solid-State Circuits Conf. Dig. Tech. Papers, February 2003, pp. 184-185.

[9] S. Mick, J. Wilson, P. Franzon, “4 Gbps High-Density AC Coupled Interconnection,” in Proc. IEEE Custom Integrated Circuits Conf., May 2002, pp. 133-140.

[10] R. J. Drost, R. David Hopkins, R. Ho, I. E. Sutherland, “Proximity Communication,” IEEE J. Solid-State Circuits, pp. 1529-1535, September 2004.

[11] K. Kanda, D. Antono, K. Ishida, H. Kawaguchi, T. Kuroda, T. Sakurai, “1.27Gb/s/pin 3mW/pin Wireless Superconnect (WSC) Interface Scheme,” in IEEE Int. Solid-State Circuits Conf. Dig. Tech. Papers, February 2003, pp. 186-187.

[12] J. Kim, J. Choi, C. Kim, M. F. Chang, I. Verbauwhede, “A Low Power Capacitive Coupled Bus Interface Based on Pulsed Signaling,” in Proc. IEEE Custom Integrated Circuits Conf., October 2004, pp. 35-38.

[13] T. J. Gabara, W. C. Fischer, “Capacitive Coupling and Quantized Feedback Applied to Conventional CMOS Technology,” IEEE J. Solid-State Circuits, pp. 419-427, March 1997.

[14] J. Kim, Z. Xu and M. F. Chang, “A 2-Gb/s/pin Source Synchronous CDMA Bus Interface with Simultaneous Multi-Chip Access and Reconfigurable I/O Capability,” in Proc. IEEE Custom Integrated Circuits Conf., September 2003, pp. 317-321.

[15] B. M, P. G, “Two High-Bandwidth Memory Bus Structures,” Design and Test of Computers, IEEE, Vol. 16, pp. 42-52, January-March 1999.

[16] B. Lau, Y. Chan, A. Moncayo, J. Ho, M. Allen, J. Salmon, J. Liu, M. Muthal, C. Lee, T. Nguyen, B. Horine, M. Leddige, K. Huang, J. Wei, L. Yu, R. Traver, Y. Hsia, R. Vu, E. Tsern, H. Liaw, J. Hudson, D. Nguyen, K. Donnelly, R. Crisp, “A 2.6 GByte/s Multipurpose Chip-to-Chip Interface,” IEEE J. Solid-State Circuits, pp. 1617-1626, November 1998.

[17] C. Yoo, K. Kyung, K. Lim, H. Lee, J. Chai, N. Heo, D. Lee, C. Kim, “A 1.8-V 700 Mb/s/pin 512-Mb DDR-II SDRAM With On-Die Termination and Off-Chip Driver Calibration,” IEEE J. Solid-State Circuits, pp. 941-951, June 2004.

Conclusion

This concludes the description of preferred embodiments of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An integrated circuit (IC) chip interconnection, comprising:
a fully alternating current (AC) coupled bus interconnect using a low power synchronous pulsed signaling scheme for board-level chip-to-chip communication.

2. The interconnection of claim 1, wherein the fully AC coupled bus interconnect comprises a multi-point, multi-drop or point-to-point bus interconnect.

3. The interconnection of claim 1, further comprising a single-ended or differential pulsed signaling transceiver, coupled to the fully AC coupled bus interconnect, for generating a diamond data eye as the pulsed signal.

4. The interconnection of claim 3, wherein the diamond data eye has a small time constant.

5. The interconnection of claim 3, wherein the transceiver includes a high-pass filter or a differentiator circuit network that generates triangle pulses comprising the diamond data eye.

6. The interconnection of claim 5, wherein the high-pass filter transmits a transient part of the pulsed signal, but blocks a direct current (DC) component of the pulsed signal.

7. The interconnection of claim 3, wherein the transceivers are coupled to the fully AC coupled bus interconnect through on-chip capacitive coupling.

8. The interconnection of claim 7, wherein the transceivers are each comprised of a transmitter and a receiver, and an on-chip capacitor decouples the transmitter and receiver from the AC coupled bus interconnect.

9. The interconnection of claim 8, wherein the transmitter includes flip-flops, a mux connected to the flip-flops, and an output driver connected to the mux, wherein the pulsed signal is induced opposite the capacitor by the output driver, based on a signal latched by the flip-flops and demultiplexed by the mux, and the pulsed signal is synchronized and transferred in parallel with an external clock.

10. The interconnection of claim 9, wherein the receiver includes a pre-amplifier, flip-flops coupled to the pre-amplifier, and a mux coupled to the flip-flops, wherein the pulsed signal arrives at the receiver in parallel with the external clock, the pulsed signal is amplified by the pre-amplifier, the amplified signal is latched by the flip-flops, and the latched signal is demultiplexed by the mux.

11. The interconnection of claim 3, wherein ends of the fully AC coupled bus interconnect are parallel terminated by impedance matching resistors.

12. A method for interconnecting integrated circuit (IC) chips, comprising:
interconnecting the IC chips using a fully alternating current (AC) coupled bus interconnect that provides a low power synchronous pulsed signaling scheme for board-level chip-to-chip communication.

13. The method of claim 12, wherein the fully AC coupled bus interconnect comprises a multi-point, multi-drop or point-to-point bus interconnect.

14. The method of claim 12, further comprising generating a diamond data eye as the pulsed signal using a single-ended or differential pulsed signaling transceiver coupled to the fully AC coupled bus interconnect.

15. The method of claim 14, wherein the diamond data eye has a small time constant.

16. The method of claim 14, wherein the transceiver includes a high-pass filter or a differentiator circuit network that generates triangle pulses comprising the diamond data eye.

17. The method of claim 16, wherein the high-pass filter transmits a transient part of the pulsed signal, but blocks a direct current (DC) component of the pulsed signal.

18. The method of claim 14, wherein the transceivers are coupled to the fully AC coupled bus interconnect through on-chip capacitive coupling.

19. The method of claim 18, wherein the transceivers are each comprised of a transmitter and a receiver, and an on-chip capacitor decouples the transmitter and receiver from the AC coupled bus interconnect.

20. The method of claim 19, wherein the transmitter includes flip-flops, a mux connected to the flip-flops, and an output driver connected to the mux, wherein the pulsed signal is induced opposite the capacitor by the output driver, based on a signal latched by the flip-flops and demultiplexed by the mux, and the pulsed signal is synchronized and transferred in parallel with an external clock.

21. The method of claim 20, wherein the receiver includes a pre-amplifier, flip-flops coupled to the pre-amplifier, and a mux coupled to the flip-flops, wherein the pulsed signal arrives at the receiver in parallel with the external clock, the pulsed signal is amplified by the pre-amplifier, the amplified signal is latched by the flip-flops, and the latched signal is demultiplexed by the mux.

22. The method of claim 14, wherein ends of the fully AC coupled bus interconnect are parallel terminated by impedance matching resistors.
